(19) United States
(12) Patent Application Publication
(10) Pub. No.: US 2024/0333226 A1
(43) Pub. Date: Oct. 3, 2024

(54) DOHERTY AMPLIFIER CIRCUIT

(71) Applicant: Murata Manufacturing Co., Ltd., Kyoto (JP)

(72) Inventor: Shohei IMAI, Kyoto (JP)

(21) Appl. No.: 18/618,180

(22) Filed: Mar. 27, 2024

(30) Foreign Application Priority Data
Mar. 31, 2023 (JP) 2023-058640

(51) Int. Cl. H03F 1/02; H03F 3/21; H03F 3/213

(52) U.S. Cl. CPC H03F 1/0288; H03F 3/211; H03F 3/213; H03F 2200/451

(57) ABSTRACT

A Doherty amplifier circuit includes a carrier amplifier that amplifies a high frequency signal, a peak amplifier that amplifies the high frequency signal, and a control circuit that detects a drive level of the carrier amplifier with reference to a detection result of an input signal of the carrier amplifier and controls the peak amplifier based on a detection result.

### CROSS REFERENCE TO RELATED APPLICATION

This application claims priority from Japanese Patent Application No. 2023-058640 filed on Mar. 31, 2023. The content of this application is incorporated herein by reference in its entirety.

### BACKGROUND ART

The present disclosure relates to a Doherty amplifier circuit.

A Doherty amplifier circuit is known as a high efficiency power amplifier circuit. The Doherty amplifier circuit is generally configured such that a carrier amplifier that operates regardless of the power level of an input signal and a peak amplifier that is turned off when the power level of the input signal is low and is turned on when the power level is high are connected in parallel. In this configuration, when the power level of the high frequency input signal is high, the carrier amplifier operates while maintaining saturation at the saturation output power level. As a result, the Doherty amplifier circuit can improve efficiency as compared with a normal power amplifier circuit.

The following United States Patent Application, Publication No. 2016/0241209, United States Patent Application, Publication No. 2020/0028472, and Japanese Unexamined Patent Application Publication No. 2019-041277 describe techniques for controlling the bias of a peak amplifier.

The technique described in United States Patent Application, Publication No. 2016/0241209 detects the saturation of the carrier amplifier with the bias circuit of the carrier amplifier interposed therebetween, and controls the bias circuit of the peak amplifier depending on the detection signal.

The technique described in United States Patent Application, Publication No. 2020/0028472 detects the saturation of the carrier amplifier by the output signal of the carrier amplifier, and controls the bias circuit of the peak amplifier depending on the detection signal.

The technique described in Japanese Unexamined Patent Application Publication No. 2019-041277 controls the bias circuit of the peak amplifier depending on the high frequency input signal level input to the Doherty amplifier circuit or the high frequency input signal level input to the carrier amplifier.

### BRIEF SUMMARY

In the techniques described in United States Patent Application, Publication No. 2016/0241209, United States Patent Application, Publication No. 2020/0028472, the circuit for detecting the saturation of the carrier amplifier requires a response time of approximately several tens of nanoseconds. Therefore, the following inconveniences may occur. For example, when a high frequency input signal having an instantaneous (a time much shorter than several tens of nanoseconds) increase in power is input to the Doherty amplifier circuit, during the period of several tens of nanoseconds from the start of saturation in the carrier amplifier until the bias point of the peak amplifier fluctuates, there may be a period of time during which the carrier amplifier is saturated. This may result in an inability to maintain high quality of the high frequency output signal in the Doherty amplifier circuit. In addition, when the Doherty amplifier circuit is applied to a communication device, it may result in an inability to maintain high communication quality.

Although the technique described in Japanese Unexamined Patent Application Publication No. 2019-041277 operates depending on the high frequency input signal level, the high frequency input signal level is detected with the bias circuit, and it is considered that the response speed is generally slow. Consequently, it is conceivable that it may result in an inability to maintain high quality of the high frequency output signal in the Doherty amplifier circuit.

The present disclosure suppresses a decrease in quality of a high frequency output signal.

A Doherty amplifier circuit according to one aspect of the present disclosure includes: a carrier amplifier that amplifies a high frequency signal; a peak amplifier that amplifies the high frequency signal; and a control circuit that detects a drive level of the carrier amplifier with reference to a detection result of an input signal of the carrier amplifier, and controls the peak amplifier based on a detection result.

According to the present disclosure, it is possible to suppress a decrease in quality of the high frequency output signal.

### BRIEF DESCRIPTION OF THE DRAWINGS

FIG. 1 is a diagram showing a configuration of a Doherty amplifier circuit of a first embodiment;

FIG. 2 is a diagram showing a specific example of a circuit configuration of a current monitoring circuit of the Doherty amplifier circuit of the first embodiment;

FIG. 3 is a diagram showing a specific example of a circuit configuration of a drive level detection circuit of the Doherty amplifier circuit of the first embodiment;

FIG. 4 is a diagram showing an example of the characteristics of the drive level detection circuit of the Doherty amplifier circuit of the first embodiment;

FIG. 5 is a diagram showing an example of the characteristics of the drive level detection circuit of the Doherty amplifier circuit of the first embodiment;

FIG. 6 is a diagram showing a first specific example of a circuit configuration of an operation circuit of the Doherty amplifier circuit of the first embodiment;

FIG. 7 is a diagram showing a second specific example of a circuit configuration of an operation circuit of the Doherty amplifier circuit of the first embodiment;

FIG. 8 is a diagram showing a configuration of a Doherty amplifier circuit of a second embodiment; and

FIG. 9 is a diagram showing a specific example of a circuit configuration of a detector circuit of the Doherty amplifier circuit of the second embodiment.

### DETAILED DESCRIPTION

Hereinafter, embodiments of the present disclosure will be described in detail with reference to the drawings. The present disclosure is not limited by the embodiments. Each embodiment is an example, and it goes without necessarily saying that partial substitution or combination of the configurations shown in different embodiments is possible. In a second embodiment and subsequent embodiments, descriptions about matters common to a first embodiment will be omitted, and only different points will be described. Particularly, the same operation and effect due to the same configuration will not be repeatedly mentioned for each embodiment.

### First Embodiment

### Overall Configuration

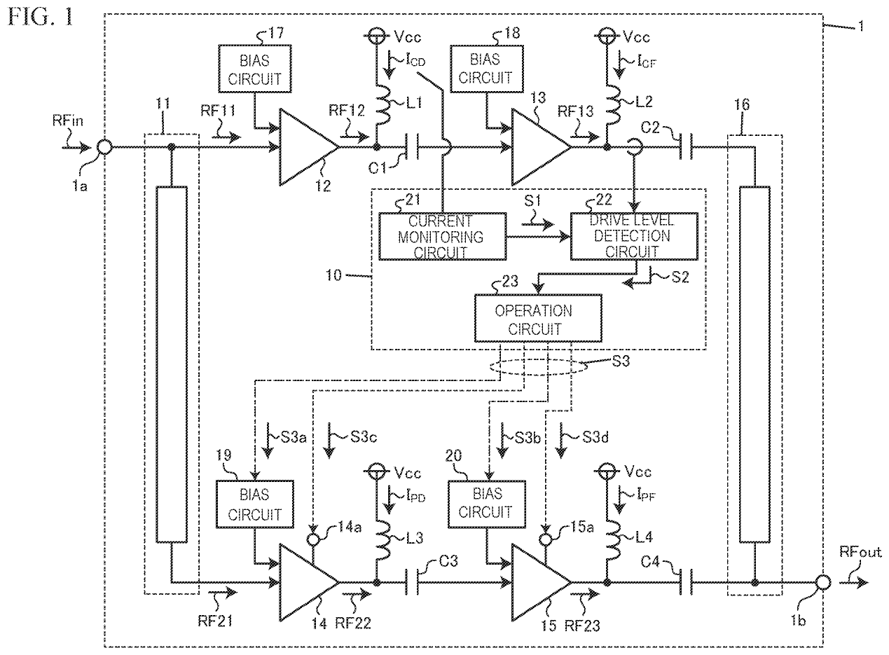

FIG. 1 is a diagram showing a configuration of a Doherty amplifier circuit of a first embodiment. A Doherty amplifier circuit 1 amplifies a high frequency signal RFin input to an input terminal 1a and outputs a high frequency signal RFout from an output terminal 1b.

The Doherty amplifier circuit 1 includes a control circuit 10, a distributor 11, a first stage (driver stage) carrier amplifier 12, a final stage (power state) carrier amplifier 13, a first stage peak amplifier 14, a final stage peak amplifier 15, a synthesizer 16, and bias circuit 17 to bias circuit 20. The control circuit 10 includes a current monitoring circuit 21, a drive level detection circuit 22, and an operation circuit 23.

In the embodiment, the number of stages of the Doherty amplifier circuit 1 is set to two stages, but the present disclosure is not limited thereto. The number of stages of the Doherty amplifier circuit 1 may be one stage or may be three or more stages.

In the embodiment, each of the carrier amplifier 12, the carrier amplifier 13, the peak amplifier 14, and the peak amplifier 15 is a single-ended amplifier, but the present disclosure is not limited thereto. Each of the carrier amplifier 12, the carrier amplifier 13, the peak amplifier 14, and the peak amplifier 15 may be a differential amplifier.

The distributor 11 divides the high frequency signal RFin input to the input terminal 1a into high frequency signals RF11 and RF21 having phases that are approximately 90° different from each other, outputs the high frequency signal RF11 to the carrier amplifier 12, and outputs the high frequency signal RF21 to the peak amplifier 14. The “approximately 90°” includes not only a 90° phase but also a 90°±45° phase.

The phase of the high frequency signal RF21 is exemplified to be delayed by 90° from the high frequency signal RF11. The power of the high frequency signal RF11 and the power of the high frequency signal RF21 are exemplified to be the same.

The bias circuit 17 applies a bias to the carrier amplifier 12. The collector of an amplifying transistor (to be described later) in the carrier amplifier 12 is electrically connected to the power supply potential Vcc with a choke coil L1 interposed therebetween. A supply current I_{CD} flows from the power supply potential Vcc to the collector of the amplifying transistor with the choke coil L1 interposed therebetween. The supply current I_{CD} is a collector current when the amplifying transistor in the carrier amplifier 12 is a bipolar transistor, and is a drain current when the amplifying transistor in the carrier amplifier 12 is a field effect transistor (FET).

The carrier amplifier 12 outputs a high frequency signal RF12, which is amplified from the high frequency signal RF11, to the carrier amplifier 13 with a capacitor C1 interposed therebetween. The capacitor C1 is a DC cut capacitor that cuts a DC component of the high frequency signal RF12.

The bias circuit 18 applies a bias to the carrier amplifier 13. The collector of the amplifying transistor in the carrier amplifier 13 is electrically connected to the power supply potential Vcc with a choke coil L2 interposed therebetween. A supply current Ice flows from the power supply potential Vcc to the collector of the amplifying transistor with the choke coil L2 interposed therebetween. The supply current Ice is a collector current when the amplifying transistor in the carrier amplifier 13 is a bipolar transistor, and is a drain current when the amplifying transistor in the carrier amplifier 13 is a field effect transistor.

The carrier amplifier 13 outputs a high frequency signal RF13, which is amplified from the high frequency signal RF12, to the synthesizer 16 with a capacitor C2 interposed therebetween. The capacitor C2 is a DC cut capacitor that cuts a DC component of the high frequency signal RF13.

The current monitoring circuit 21 monitors the supply current I_{CD} and outputs a signal S1 representing the supply current I_{CD} to the drive level detection circuit 22.

The drive level detection circuit 22 sets the sensitivity (gain) or the threshold value by the signal S1, detects the drive level (operation level) of the carrier amplifier 13 based on the high frequency signal RF13, and outputs a signal S2 representing the drive level of the carrier amplifier 13 to the operation circuit 23. In other words, the drive level detection circuit 22 outputs the signal S2 representing the drive level of the carrier amplifier 13 to the operation circuit 23, based on both the detection result of the input signal to the carrier amplifier 13, which is output from the current monitoring circuit 21, and the high frequency signal RF13, which is output from the carrier amplifier 13. The signal S2 may be a signal (inversion signal) that changes complementarily to the drive level of the carrier amplifier 13.

The operation circuit 23 adds an operation to the signal S2 and outputs a signal S3. The operation circuit 23 is exemplified to output the signal S2 directly as the signal S3, for example. In addition, the operation circuit 23 is exemplified to output the signal S3 by inverting and amplifying the signal S2. However, the present disclosure is not limited thereto. The signal S3 is exemplified to include signals S3a, S3b, S3c, and S3d.

As a specific example (to be described later), the operation circuit 23 outputs the signal S3a to the bias circuit 19 and outputs the signal S3b to the bias circuit 20. When outputting a current signal, the operation circuit 23 may respectively output separate signal S3a and signal S3b to the bias circuit 19 and the bias circuit 20, as shown in FIG. 1. When outputting a voltage signal, the operation circuit 23 may output one common signal S3 to the bias circuit 19 and the bias circuit 20.

The operation circuit 23 may output only one of the signal S3a and the signal S3b. That is, the operation circuit 23 may output the signal S3a to the bias circuit 19 and need not output the signal S3b to the bias circuit 20. Alternatively, the operation circuit 23 may output the signal S3b to the bias circuit 20 and need not output the signal S3a to the bias circuit 19.

As a specific example (to be described later), the operation circuit 23 outputs a signal S3c to an enable terminal 14a (to be described later) of the peak amplifier 14 and outputs a signal S3d to an enable terminal 15a of the peak amplifier 15. When outputting a current signal, the operation circuit 23 may respectively output separate signal S3c and signal S3d to the enable terminal 14a of the peak amplifier 14 and the enable terminal 15a of the peak amplifier 15, as shown in FIG. 1. When outputting a voltage signal, the operation circuit 23 may output one common signal S3 to the enable terminal 14a of the peak amplifier 14 and the enable terminal 15a of the peak amplifier 15.

The operation circuit 23 may output only one of the signal S3c and the signal S3d. That is, the operation circuit 23 may output the signal S3c to the enable terminal 14a of the peak amplifier 14 and need not output the signal S3d to the enable terminal 15a of the peak amplifier 15. Alternatively, the operation circuit 23 may output the signal S3d to the enable terminal 15a of the peak amplifier 15 and need not output the signal S3c to the enable terminal 14a of the peak amplifier 14.

The signal S3a can be input to the bias circuit 19 from the operation circuit 23. When the signal S3a is input, the bias circuit 19 applies the bias based on the signal S3a to the peak amplifier 14. When the signal S3a is not input, the bias circuit 19 applies a predetermined bias to the peak amplifier 14.

The collector or drain of the amplifying transistor (to be described later) in the peak amplifier 14 is electrically connected to the power supply potential Vcc with a choke coil L3 interposed therebetween. A supply current I_{PD} flows from the power supply potential Vcc to the collector or drain of the amplifying transistor with the choke coil L3 interposed therebetween. The supply current I_{PD} is a collector current when the amplifying transistor in the peak amplifier 14 is a bipolar transistor, and is a drain current when the amplifying transistor in the peak amplifier 14 is a field effect transistor.

The peak amplifier 14 has an enable terminal 14a for controlling an operation state (high frequency signal amplification state) and a non-operation state (high frequency signal non-amplification state). The signal S3c can be input to the enable terminal 14a from the operation circuit 23. The peak amplifier 14 can be controlled to be in the operation state or the non-operation state depending on the signal S3c.

In the case of the operation state, the peak amplifier 14 outputs the high frequency signal RF22, which is amplified from the high frequency signal RF21, to the peak amplifier 15 with a capacitor C3 interposed therebetween. The capacitor C3 is a DC cut capacitor that cuts a DC component of the high frequency signal RF22. The peak amplifier 14 does not amplify the high frequency signal RF21 in the non-operation state.

The signal S3b can be input to the bias circuit 20 from the operation circuit 23. When the signal S3b is input, the bias circuit 20 applies the bias based on the signal S3b to the peak amplifier 15. When the signal S3b is not input, the bias circuit 20 applies a predetermined bias to the peak amplifier 15.

The collector or drain of the amplifying transistor in the peak amplifier 15 is electrically connected to the power supply potential Vcc with a choke coil L4 interposed therebetween. A supply current I_{PF} flows from the power supply potential Vcc to the collector or drain of the amplifying transistor with the choke coil L4 interposed therebetween. The supply current I_{PF} is a collector current when the amplifying transistor in the peak amplifier 15 is a bipolar transistor, and is a drain current when the amplifying transistor in the peak amplifier 15 is a field effect transistor.

The peak amplifier 15 has an enable terminal 15a for controlling the operation state and the non-operation state. The signal S3d can be input to the enable terminal 15a from the operation circuit 23. The peak amplifier 15 can be controlled to be in the operation state or the non-operation state depending on the signal S3d.

In the case of the operation state, the peak amplifier 15 outputs the high frequency signal RF23, which is amplified from the high frequency signal RF22, to the synthesizer 16 with a capacitor C4 interposed therebetween. The capacitor C4 is a DC cut capacitor that cuts a DC component of the high frequency signal RF23. The peak amplifier 15 does not amplify the high frequency signal RF22 in the non-operation state.

When the peak amplifier 14 and the peak amplifier 15 are in the non-operation state, the synthesizer 16 outputs the high frequency signal RF3 as the high frequency signal RFout. When the peak amplifier 14 and the peak amplifier 15 are in the operation state, the synthesizer 16 couples and synthesizes the high frequency signal RF13 and the high frequency signal RF23, and outputs the high frequency signal RFout.

### Effects

The supply current I_{CD} of the carrier amplifier 12 is a current that changes depending on the intensity of the high frequency signal RF11 input to the carrier amplifier 12, and is a current in which the operation state of the carrier amplifier 12, that is, the signal level of the high frequency signal RF12 which is the input signal of the carrier amplifier 13 is reflected. Here, the high frequency signal RF11 is input to the carrier amplifier 12 earlier than the high frequency signal RF13 is input to the carrier amplifier 13. In other words, the operation state of the carrier amplifier 12 changes faster compared to the operation state of the carrier amplifier 13. The current monitoring circuit 21 can detect the intensity of the high frequency signal RF11 in which the operation state of the carrier amplifier 12 that changes faster compared to the operation state of the carrier amplifier 13 is reflected by monitoring the supply current I_{CD} of the carrier amplifier 12. The current monitoring circuit 21 sets the sensitivity or the threshold value of the drive level detection circuit 22 with reference to the monitored supply current I_{CD} of the carrier amplifier 12, and the drive level detection circuit 22 detects the saturation of the carrier amplifier 13 with the set sensitivity or threshold value. In other words, the drive level detection circuit 22 detects the saturation of the carrier amplifier 13 with the set sensitivity or threshold value reflecting the operation state of the carrier amplifier 12 that changes faster compared to the operation state of the carrier amplifier 13. Therefore, the Doherty amplifier circuit 1 can rapidly activate the peak amplifier 14 and the peak amplifier 15 as compared to United States Patent Application, Publication No. 2016/0241209, United States Patent Application, Publication No. 2020/0028472, and Japanese Unexamined Patent Application Publication No. 2019-041277. Accordingly, the Doherty amplifier circuit 1 can suppress a decrease in quality of the high frequency signal RFout.

The Doherty amplifier circuit 1 can be considered to operate in a feedforward manner depending on the supply current I_{CD} and to operate in a feedback manner depending on the drive level of the carrier amplifier 13.

### Specific Example of Circuit Configuration of Current Monitoring Circuit

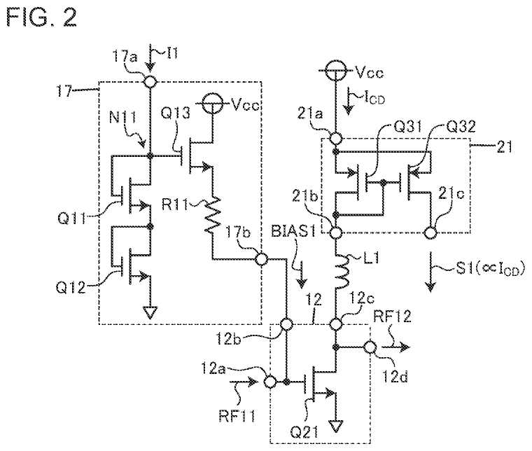

FIG. 2 is a diagram showing a specific example of a circuit configuration of a current monitoring circuit of the Doherty amplifier circuit of the first embodiment.

In FIG. 2, the circuit configuration of the bias circuit 17 is shown, but the circuit configuration of the bias circuit 18 is the same as the circuit configuration of the bias circuit 17, so that the illustration and description are omitted. In addition, in FIG. 2, the circuit configuration of the carrier amplifier 12 is shown, but the circuit configuration of the carrier amplifier 13 is also the same as the circuit configuration of the carrier amplifier 12, so that the illustration and description are omitted.

The bias circuit 17 includes N-channel transistors Q11, Q12, and Q13, and a resistor R11.

Each transistor is a field effect transistor, but the present disclosure is not limited thereto. The transistor may be, for example, a bipolar transistor. Examples of the bipolar transistor include a heterojunction bipolar transistor (HBT), but the present disclosure is not limited thereto. The transistor may be a multi-finger transistor in which a plurality of unit transistors are electrically connected in parallel. The unit transistor refers to the minimum configuration in which a transistor is configured.

When each transistor is a bipolar transistor, the emitter corresponds to the source of the FET, the base corresponds to the gate of the FET, and the collector corresponds to the drain of the FET.

A setting current I1 is input to a terminal 17a of the bias circuit 17.

The gate and the drain of the transistor Q11 are electrically connected to the terminal 17a with a node N11 interposed therebetween. That is, the transistor Q11 is diode-connected.

The gate and the drain of the transistor Q12 are electrically connected to the source of the transistor Q11. That is, the transistor Q12 is diode-connected. The source of the transistor Q12 is electrically connected to the reference potential. The reference potential is exemplified by the ground potential, but the present disclosure is not limited thereto.

The transistor Q11 and the transistor Q12 generate a voltage depending on the setting current I1. This voltage is the voltage at the node N11.

The drain of the transistor Q13 is electrically connected to the power supply potential Vcc. The gate of the transistor Q13 is electrically connected to the node N11. The source of the transistor Q13 is electrically connected to one end of the resistor R11. That is, the transistor Q13 and the resistor R11 are source follower-connected. The other end of the resistor R11 is electrically connected to a terminal 17b.

The transistor Q13 outputs a bias voltage or a bias current BIAS1 depending on the voltage of the node N11 from the terminal 17b with the resistor R11 interposed therebetween.

The carrier amplifier 12 includes a transistor Q21.

The high frequency signal RF11 is input to a terminal 12a of the carrier amplifier 12. The bias voltage or the bias current BIAS1 is input to a terminal 12b of the carrier amplifier 12. The supply current I_{CD} is input to a terminal 12c of the carrier amplifier 12 from one end of the choke coil L1.

The gate of the transistor Q21 is electrically connected to the terminal 12a and the terminal 12b. The drain of the transistor Q21 is electrically connected to the terminal 12c and the terminal 12d. The source of the transistor Q21 is electrically connected to the reference potential.

The bias voltage or the bias current BIAS1 is input to the gate of the transistor Q21 from the terminal 12b. In addition, the high frequency signal RF11 is input to the gate of the transistor Q21 from the terminal 12a. The supply current Icp is input to the drain of the transistor Q21 from the terminal 12c.

The transistor Q21 amplifies the high frequency signal RF11 and outputs the high frequency signal RF12 from the terminal 12d.

The current monitoring circuit 21 includes a P-channel transistor Q31 and a transistor Q32.

A terminal 21a of the current monitoring circuit 21 is electrically connected to the power supply potential Vcc. A terminal 21b of the current monitoring circuit 21 is electrically connected to the other end of the choke coil L1.

The source of the transistor Q31 is electrically connected to the terminal 21a. The gate and the drain of the transistor Q31 are electrically connected to the terminal 21b. That is, the transistor Q31 is diode-connected. The supply current I_{CD} of the transistor Q21 flows through the source-drain path of the transistor Q31.

The source of the transistor Q32 is electrically connected to the source of the transistor Q31. The gate of the transistor Q32 is electrically connected to the gate of the transistor Q31. That is, the transistor Q31 and the transistor Q32 are current-mirror connected. The drain of the transistor Q32 is electrically connected to a terminal 21c.

The transistor Q32 outputs a current proportional to the supply current I_{CD} from the terminal 21c as the signal S1. That is, the current value of the signal S1 is proportional to the current value of the supply current I_{CD}.

As described above, the current monitoring circuit 21 can monitor the supply current I_{CD} and output the signal S1 depending on the supply current I_{CD}.

### Specific Example of Circuit Configuration of Drive Level Detection Circuit

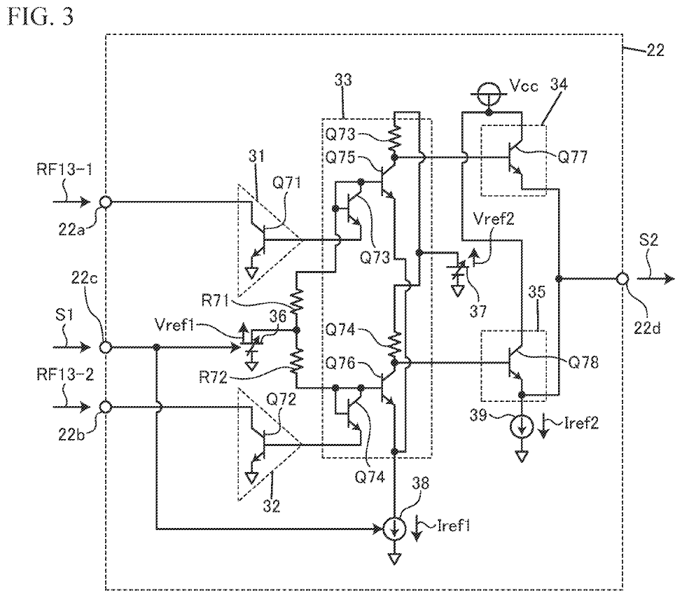

FIG. 3 is a diagram showing a specific example of a circuit configuration of a drive level detection circuit of the Doherty amplifier circuit of the first embodiment.

The drive level detection circuit 22 is input with a first-phase high frequency signal RF13-1 and a second-phase high frequency signal RF13-2 that configure a pair of differential signals. The first-phase high frequency signal RF13-1 is input to a terminal 22a of the drive level detection circuit 22. The second-phase high frequency signal RF13-2 is input to a terminal 22b of the drive level detection circuit 22.

When the carrier amplifier 13 (refer to FIG. 1) is a differential amplifier, the carrier amplifier 13 outputs the first-phase high frequency signal RF13-1 and the second-phase high frequency signal RF13-2 to the drive level detection circuit 22. When the carrier amplifier 13 is a single-ended amplifier, a balun may be used. The single-ended high frequency signal RF13 output from the carrier amplifier 13 is input to the balun. The balun converts the single-ended high frequency signal RF13 into the first-phase high frequency signal RF13-1 and the second-phase high frequency signal RF13-2, and outputs the first-phase high frequency signal RF13-1 and the second-phase high frequency signal RF13-2 to the drive level detection circuit 22.

Hereinafter, the first-phase high frequency signal RF13-1 and the second-phase high frequency signal RF13-2 may be collectively referred to as the high frequency signal RF13.

The signal S1 is input to a terminal 22c of the drive level detection circuit 22.

The drive level detection circuit 22 outputs the signal S2 from a terminal 22d.

The drive level detection circuit 22 includes comparator sections 31 and 32, a differential amplifier 33, detection sections 34 and 35, voltage sources 36 and 37, current sources 38 and 39, and resistors R71 and R72.

The comparator section 31 is a comparator and includes a transistor Q71. The comparator section 32 is a comparator and includes a transistor Q72.

The differential amplifier 33 includes transistors Q73 to Q76, and resistors R73 and R74.

The detection section 34 includes a transistor Q77. The detection section 35 includes a transistor Q78.

The signal S1 can be input to the voltage source 36. When the signal S1 is input, the voltage source 36 outputs a voltage Vref1 depending on the signal S1. When the signal S1 is not input, the voltage source 36 outputs a constant voltage Vref1.

The signal S1 can be input to the current source 38. When the signal S1 is input, the current source 38 outputs a current Iref1 depending on the signal S1. When the signal S1 is not input, the current source 38 outputs a constant current Iref1.

In the embodiment, the signal S1 is input to both the voltage source 36 and the current source 38, but the present disclosure is not limited thereto. The signal S1 may be input to at least one of the voltage source 36 and the current source 38.

A voltage source 37 outputs a constant voltage Vref2. A current source 39 outputs a constant current Iref2.

The collector of the transistor Q71 of the comparator section 31 is electrically connected to the terminal 22a. The first-phase high frequency signal RF13-1 is input to the collector of the transistor Q71. The emitter of the transistor Q71 is electrically connected to the reference potential. The base of the transistor Q71 is electrically connected to the emitter of the transistor Q73.

The transistor Q71 is a comparator that compares the voltage of the collector with the voltage of the base. The transistor Q71 implements the function of the comparator by using a phenomenon in which the base current increases when the potential of the collector (first-phase high frequency signal RF13-1) is lower than the voltage V_{be} (threshold value) between the base and the emitter.

The collector of the transistor Q72 in the comparator section 32 is electrically connected to the terminal 22b. The second-phase high frequency signal RF13-2 is input to the collector of the transistor Q72. The emitter of the transistor Q72 is electrically connected to the reference potential. The base of the transistor Q72 is electrically connected to the emitter of the transistor Q74.

The transistor Q72 is a comparator that compares the voltage of the collector with the voltage of the base. The transistor Q72 implements the function of the comparator by using a phenomenon in which the base current increases when the potential of the collector (second-phase high frequency signal RF13-2) is lower than the voltage V_{be} (threshold value) between the base and the emitter.

The differential amplifier 33 amplifies a pair of differential signals output from the comparator sections 31 and 32 and outputs the amplified signals to the detection sections 34 and 35.

The base of the transistor Q75 is electrically connected to the high voltage side end of the voltage source 36 with the resistor R71 interposed therebetween. The emitter of the transistor Q75 is electrically connected to the current source 38. The collector of the transistor Q75 is electrically connected to the base of the transistor Q77.

The collector and the base of the transistor Q73 are electrically connected to the high potential side end of the voltage source 36 with the resistor R71 interposed therebetween. That is, the transistor Q73 is diode-connected. The collector and the base of the transistor Q73 are electrically connected to the base of the transistor Q75. The emitter of the transistor Q73 is electrically connected to the base of the transistor Q71.

The base of the transistor Q76 is electrically connected to the high voltage side end of the voltage source 36 with the resistor R72 interposed therebetween. The emitter of the transistor Q76 is electrically connected to the current source 38. The collector of the transistor Q76 is electrically connected to the base of the transistor Q78.

The collector and the base of the transistor Q74 are electrically connected to the high voltage side end of the voltage source 36 with the resistor R72 interposed therebetween. That is, the transistor Q74 is diode-connected. The collector and the base of the transistor Q74 are electrically connected to the base of the transistor Q76. The emitter of the transistor Q74 is electrically connected to the base of the transistor Q72.

The collector of the transistor Q75 is electrically connected to the high voltage side end of the voltage source 37 with a resistor R73 interposed therebetween. The voltage source 37 outputs the voltage Vref2 to the collector of the transistor Q75. Similarly, the collector of the transistor Q76 is electrically connected to the high voltage side end of the voltage source 37 with a resistor R74 interposed therebetween. The voltage source 37 outputs the voltage Vref2 to the collector of the transistor Q76.

Here, each of the transistor Q73 and the transistor Q74 is, for example, a transistor for raising the voltage of the transistor Q75 and the transistor Q76 only by the voltage indicated by the current source 38.

In the differential amplifier 33, when the current Iref1 increases, the collector current of the transistors Q75 and Q76 increases, and the current amplification factor β of the transistors Q75 and 076 increases, and thus the gain increases. In the differential amplifier 33, when the current Iref1 decreases, the collector current of the transistors Q75 and Q76 decreases, and the current amplification factor ß of the transistors Q75 and Q76 decreases, and thus the gain decreases.

The bias of the comparator section 31, the transistor Q75, the comparator section 32, and the transistor Q76 is implemented with the voltage Vref1, but the present disclosure is not limited thereto. The bias may be provided for each of the comparator section 31, the transistor Q75, the comparator section 32, and the transistor Q76. That is, a bias circuit may be provided for each transistor. In this case, each of the transistor Q73 and the transistor Q74 that raises the voltage indicated by the current source 38 may be replaced with a capacitor that allows the high frequency signal RF13 to pass therethrough.

The collector of the transistor Q77 of the detection section 34 is electrically connected to the power supply potential Vcc. The base of the transistor Q77 is electrically connected to the collector of the transistor Q75. The emitter of the transistor Q77 is electrically connected to the terminal 22d and electrically connected to the current source 39.

The collector of the transistor Q78 of the detection section 35 is electrically connected to the power supply potential Vcc. The base of the transistor Q78 is electrically connected to the collector of the transistor Q76. The emitter of the transistor Q78 is electrically connected to the terminal 22d and electrically connected to the current source 39.

The detection sections 34 and 35 convert a pair of differential signals output from the differential amplifier 33 into a single-ended signal S2 and output the single-ended signal S2 from the terminal 22d.

As described above, the threshold value of the drive level detection circuit 22, that is, the voltage Vref1 of the voltage source 36 can be set by the signal S1.

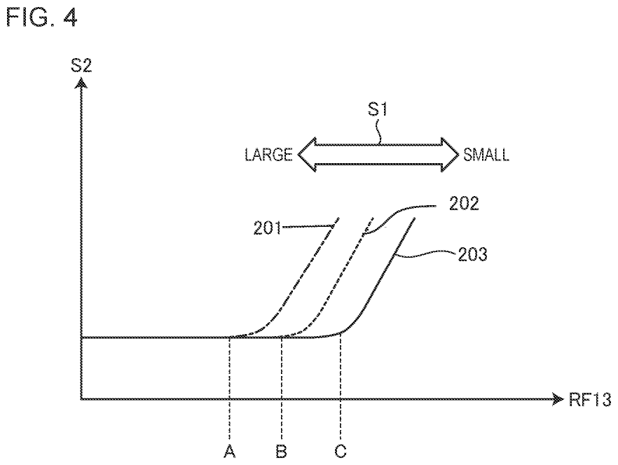

FIG. 4 is a diagram showing an example of the characteristics of the drive level detection circuit of the Doherty amplifier circuit of the first embodiment.

In FIG. 4, the vertical axis represents the signal S2, and the horizontal axis represents the high frequency signal RF13.

When the signal S1 is large, a small threshold value A is set in the drive level detection circuit 22. When the signal S1 is small, a large threshold value C is set in the drive level detection circuit 22. When the signal S1 is intermediate, an intermediate threshold value B is set in the drive level detection circuit 22. That is, A<B<C.

When the signal S1 is large, that is, when the supply current I_{CD} of the carrier amplifier 12 (refer to FIG. 2) is large, there is a high possibility that the carrier amplifier 13 will reach saturation in consideration of external factors such as load fluctuations and power supply voltage fluctuations. Therefore, the drive level detection circuit 22 starts to output the signal S2 even if a small threshold value A is set and the high frequency signal RF13 is small.

When the signal S1 is small, that is, when the supply current I_{CD} of the carrier amplifier 12 is small, the carrier amplifier 13 is less likely to saturate. Therefore, the drive level detection circuit 22 starts to output the signal S2 when a large threshold value C is set and the high frequency signal RF13 increases.

When the signal S1 is intermediate, that is, when the supply current I_{CD} of the carrier amplifier 12 is intermediate, the saturation tendency of the carrier amplifier 13 becomes intermediate. Therefore, the drive level detection circuit 22 starts to output the signal S2 when an intermediate threshold value B is set and the high frequency signal RF13 becomes intermediate.

In addition, as described above, the sensitivity of the drive level detection circuit 22, that is, the current Iref1 of the current source 38 can be set by the signal S1.

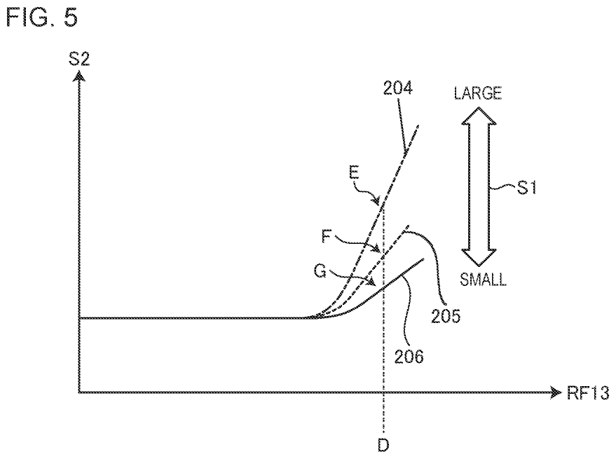

FIG. 5 is a diagram showing an example of the characteristics of the drive level detection circuit of the Doherty amplifier circuit of the first embodiment.

In FIG. 5, the vertical axis represents the signal S2, and the horizontal axis represents the high frequency signal RF13.

When the signal S1 is large, a large sensitivity (gain) is set in the drive level detection circuit 22. When the signal S1 is small, a small sensitivity (gain) is set in the drive level detection circuit 22. When the signal S1 is intermediate, an intermediate sensitivity (gain) is set in the drive level detection circuit 22.

When the signal S1 is large, that is, when the supply current I_{CD} of the carrier amplifier 12 (refer to FIG. 2) is large, the carrier amplifier 13 is likely to saturate easily. Therefore, the drive level detection circuit 22 outputs the signal S2 having a large value E when a large gain is set and the value of the high frequency signal RF13 is D.

When the signal S1 is small, that is, when the supply current I_{CD} of the carrier amplifier 12 is small, the carrier amplifier 13 is less likely to saturate. Therefore, the drive level detection circuit 22 outputs the signal S2 having a small value G when a small gain is set and the value of the high frequency signal RF13 is D.

When the signal S1 is intermediate, that is, when the supply current I_{CD} of the carrier amplifier 12 is intermediate, the saturation tendency of the carrier amplifier 13 becomes intermediate. Therefore, the drive level detection circuit 22 outputs the signal S2 having an intermediate value F when an intermediate gain is set and the value of the high frequency signal RF13 is D.

That is, E>F>G.

The drive level detection circuit 22 sets the sensitivity (gain) or the threshold value by the signal S1, and detects the drive level (operation level) of the carrier amplifier 13 based on the high frequency signal RF13, and can output the signal S2 representing the drive level of the carrier amplifier 13.

### First Specific Example of Circuit Configuration of Operation Circuit

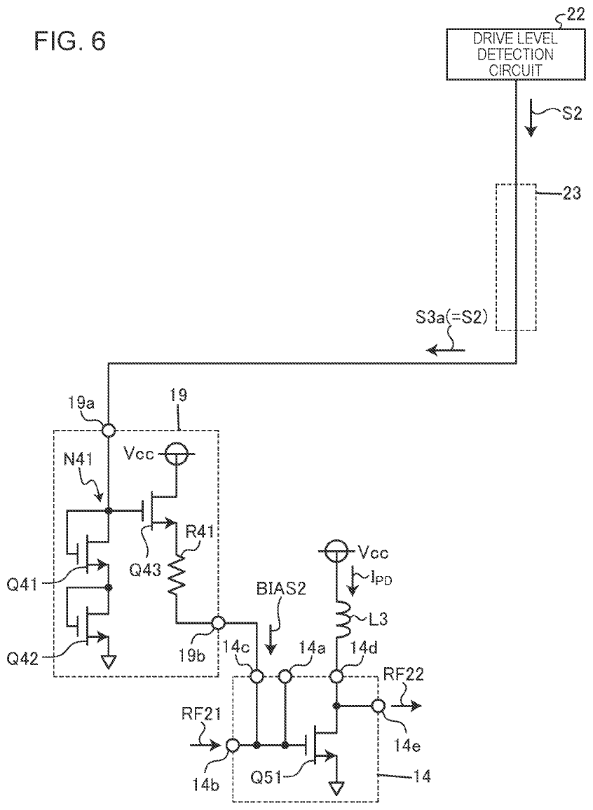

FIG. 6 is a diagram showing a first specific example of a circuit configuration of an operation circuit of the Doherty amplifier circuit of the first embodiment.

As shown in FIG. 6, when the signal S3a is input to the bias circuit 19, the operation circuit 23 is optional. In this case, the signal S3a is the signal S2.

The bias circuit 19 includes N-channel transistors Q41, Q42, and Q43, and a resistor R41.

The signal S3a is input to a terminal 19a of the bias circuit 19.

The connection relationship of the transistor Q41, the transistor Q42, the transistor Q43, the resistor R41, and a node N41 is the same as the connection relationship of the transistor Q11, the transistor Q12, the transistor Q13, the resistor R11, and the node N11 (refer to FIG. 2), and thus the description thereof will be omitted.

In FIG. 6, the circuit configuration of the bias circuit 19 is shown, but the circuit configuration of the bias circuit 20 is the same as the circuit configuration of the bias circuit 19, so that the illustration and description are omitted.

The transistor Q43 outputs a bias voltage or a bias current BIAS2 depending on the voltage of the node N41 from the terminal 19b with the resistor R41 interposed therebetween.

The peak amplifier 14 includes a transistor Q51.

In FIG. 6, the circuit configuration of the peak amplifier 14 is shown, but the circuit configuration of the peak amplifier 15 is the same as the circuit configuration of the peak amplifier 14, so that the illustration and description are omitted.

In the first specific example, no signal is input to the enable terminal 14a of the peak amplifier 14. The high frequency signal RF21 is input to a terminal 14b of the peak amplifier 14. The bias voltage or the bias current BIAS2 is input to a terminal 14c of the peak amplifier 14. The supply current I_{PD} is input to a terminal 14d of the peak amplifier 14 from one end of the choke coil L3.

The gate of the transistor Q51 is electrically connected to the enable terminal 14a, the terminal 14b, and the terminal 14c. The drain of the transistor Q51 is electrically connected to the terminal 14d and the terminal 14e. The source of the transistor Q51 is electrically connected to the reference potential.

The bias voltage or the bias current BIAS2 is input to the gate of the transistor Q51 from the terminal 14c. In addition, the high frequency signal RF21 is input to the gate of the transistor Q51 from the terminal 14b. The supply current I_{PD} is input to the drain of the transistor Q51 from the terminal 14d.

The transistor Q51 amplifies the high frequency signal RF21 and outputs the high frequency signal RF22 from the terminal 14e.

The operations of the carrier amplifier 13, the drive level detection circuit 22, the bias circuit 19, and the peak amplifier 14 will be described.

When the carrier amplifier 13 is close to a saturation state, the drive level detection circuit 22 increases the signal S2 (=signal S3a). Therefore, the bias circuit 19 increases the bias voltage or the bias current BIAS2. Accordingly, the peak amplifier 14 performs an amplification operation.

When the carrier amplifier 13 is not close to a saturation state, the drive level detection circuit 22 decreases the signal S1 (=signal S3a). Therefore, the bias circuit 19 decreases the bias voltage or the bias current BIAS2. Accordingly, the peak amplifier 14 does not perform an amplification operation.

### Second Specific Example of Circuit Configuration of Operation Circuit

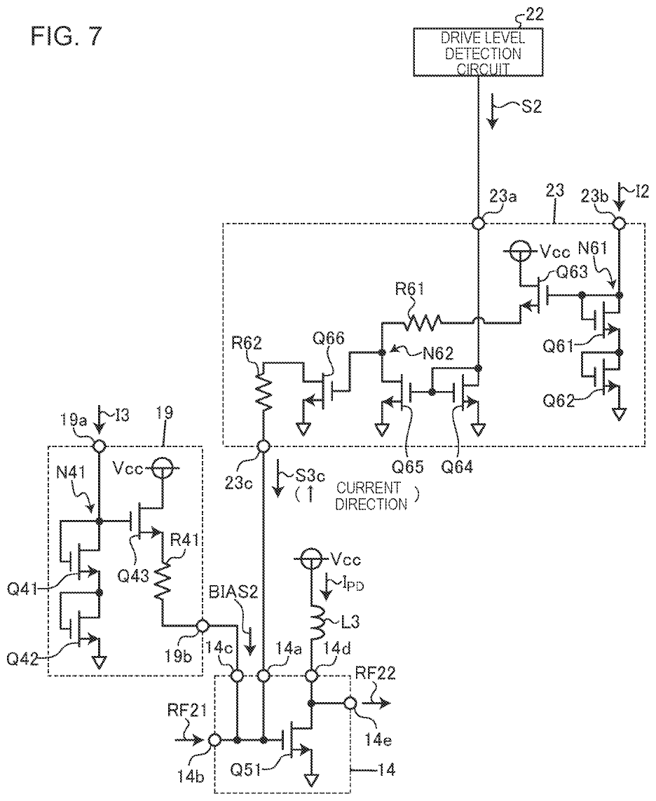

FIG. 7 is a diagram showing a second specific example of a circuit configuration of an operation circuit of the Doherty amplifier circuit of the first embodiment.

In the example shown in FIG. 7, the signal S3c is input to the enable terminal 14a of the peak amplifier 14, and the signal S3a is not input to the terminal 19a of the bias circuit 19. A setting current I3 is input to the terminal 19a of the bias circuit 19 instead of the signal S3a.

In the present example, the operation circuit 23 is an inverting amplifier circuit, but the present disclosure is not limited thereto.

The operation circuit 23 includes transistors Q61 to Q66, and resistors R61 and R62.

The signal S2 is input to a terminal 23a of the operation circuit 23. A setting current I2 is input to a terminal 23b of the operation circuit 23.

The gate and the drain of the transistor Q61 are electrically connected to the terminal 23b with a node N61 interposed therebetween. That is, the transistor Q61 is diode-connected.

The gate and the drain of the transistor Q62 are electrically connected to the source of the transistor Q61. That is, the transistor Q62 is diode-connected. The source of the transistor Q62 is electrically connected to the reference potential.

The transistor Q61 and the transistor Q62 generate a voltage depending on the setting current I2. This voltage is the voltage at the node N61.

The drain of the transistor Q63 is electrically connected to the power supply potential Vcc. The gate of the transistor Q63 is electrically connected to the node N61. The source of the transistor Q63 is electrically connected to one end of the resistor R61. That is, the transistor Q63 and the resistor R61 are source follower-connected. The other end of the resistor R61 is electrically connected to a node N62.

The transistor Q63 can output a current depending on the voltage of the node N61 to the node N62.

The drain and the gate of the transistor Q64 are electrically connected to the terminal 23a. That is, the transistor Q64 is diode-connected. The source of the transistor Q64 is electrically connected to the reference potential. The signal S2 flows through the drain-source path of the transistor Q64.

The source of the transistor Q65 is electrically connected to the reference potential. The gate of the transistor Q65 is electrically connected to the drain and the gate of the transistor Q64. That is, the transistor Q64 and the transistor Q65 are current-mirror connected. The drain of the transistor Q65 is electrically connected to the node N62.

The source of the transistor Q66 is electrically connected to the reference potential. The gate of the transistor Q66 is electrically connected to the node N62. The drain of the transistor Q66 is electrically connected to one end of the resistor R62. The other end of the resistor R62 is electrically connected to a terminal 23c. The transistor Q66 causes a current depending on the voltage of the node N62 to flow from the terminal 23c toward the reference potential.

The terminal 23c is electrically connected to the enable terminal 14a of the peak amplifier 14. The operation circuit 23 draws a current from the enable terminal 14a of the peak amplifier 14 depending on the signal S2. That is, the signal S3c is a current in a direction from the enable terminal 14a of the peak amplifier 14 to the terminal 23c.

The operation of the operation circuit 23 will be described.

When the intensity of the high frequency signal RF11 input to the carrier amplifier 12 is high and the power input to the carrier amplifier 12 is high, the drive level detection circuit 22 increases the signal S2. When the signal S2 increases, the gate potential of the transistor Q64 rises, the gate voltage of the transistor Q65 also rises, and the current flowing through the path from the source of the transistor Q63, through the resistor R61, to the node N62, then to the drain of the transistor Q65, and further to the source of the transistor Q65, and to the reference potential, increases. Then, the voltage drop across the resistor R61 increases, so that the voltage of the node N62 decreases. As a result, the gate voltage of the transistor Q66 decreases, and thus the transistor Q66 enters the off state. Therefore, the current (signal S3c) flowing through the path from the enable terminal 14a of the peak amplifier 14, to the terminal 23c of the operation circuit 23, through the resistor R62, to the drain of the transistor Q66, and further to the source of the transistor Q66, and to the reference potential, decreases. That is, the current flowing from the terminal 14c of the peak amplifier 14 to the enable terminal 14a of the peak amplifier 14 decreases, and the bias applied to the transistor Q51 increases. Accordingly, the peak amplifier 14 performs an amplification operation.

When the intensity of the high frequency signal RF11 input to the carrier amplifier 12 is low and the power input to the carrier amplifier 12 is small, the drive level detection circuit 22 decreases the signal S2. When the signal S2 decreases, the gate potential of the transistor Q64 falls, the gate voltage of the transistor Q65 also falls, and the current flowing through the path from the source of the transistor Q63, through the resistor R61, to the node N62, then to the drain of the transistor Q65, and further to the source of the transistor Q65, and to the reference potential, decreases. Then, the voltage drop across the resistor R61 decreases, so that the voltage of the node N62 rises. As a result, the gate voltage of the transistor Q66 rises, and thus the transistor Q66 enters the on state. Therefore, the current (signal S3c) flowing through the path from the enable terminal 14a of the peak amplifier 14, to the terminal 23c of the operation circuit 23, through the resistor R62, to the drain of the transistor Q66, and further to the source of the transistor Q66, and to the reference potential, increases. That is, the current flowing from the terminal 14c of the peak amplifier 14 to the enable terminal 14a of the peak amplifier 14 increases, and the bias applied to the transistor Q51 decreases. Accordingly, the peak amplifier 14 does not perform an amplification operation.

In the first specific example, the signal S3a is input to the bias circuit 19, and the bias circuit 19 outputs the bias voltage or the bias current BIAS2 based on the signal S3a. Therefore, in the first specific example, it is difficult to set the bias of the peak amplifier 14 at the time of idling to a desired value.

On the other hand, in the second specific example, since the signal S3c is input to the enable terminal 14a of the peak amplifier 14, the bias voltage or the bias current BIAS2, and the signal S3c can be controlled separately. Accordingly, in the second specific example, it is easy to set the bias of the peak amplifier 14 at the time of idling to a desired value.

### Second Embodiment

### Overall Configuration

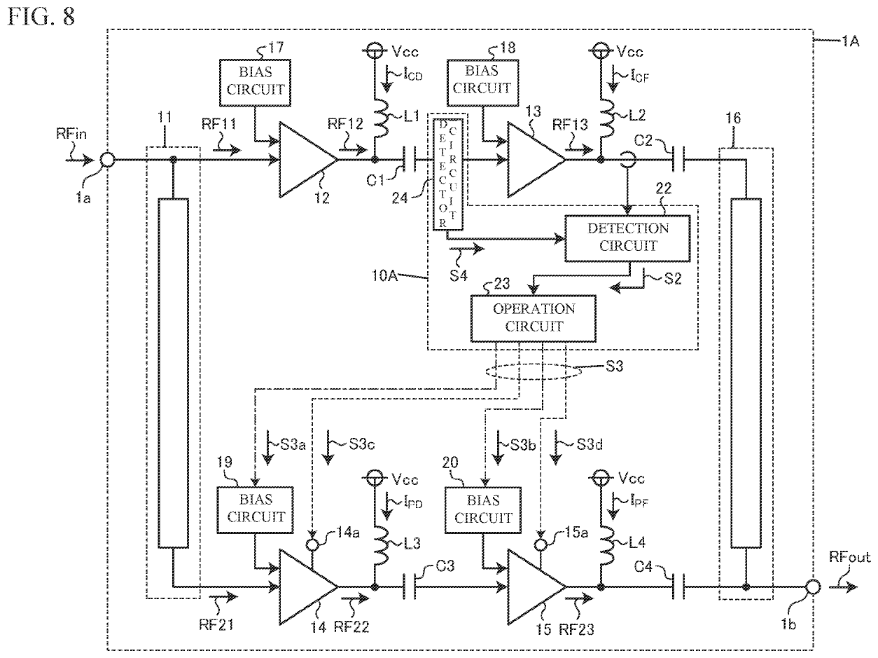

FIG. 8 is a diagram showing a configuration of a Doherty amplifier circuit of a second embodiment.

A Doherty amplifier circuit 1A includes a control circuit 10A instead of the control circuit 10, as compared to the Doherty amplifier circuit 1 (refer to FIG. 1). The control circuit 10A includes a detector circuit 24 instead of the current monitoring circuit 21, as compared to the control circuit 10.

The detector circuit 24 detects the high frequency signal RF12 and outputs the signal S4 to the drive level detection circuit 22. The drive level detection circuit 22 sets the sensitivity (gain) or the threshold value by the signal S4 instead of the signal S1 (refer to FIG. 1).

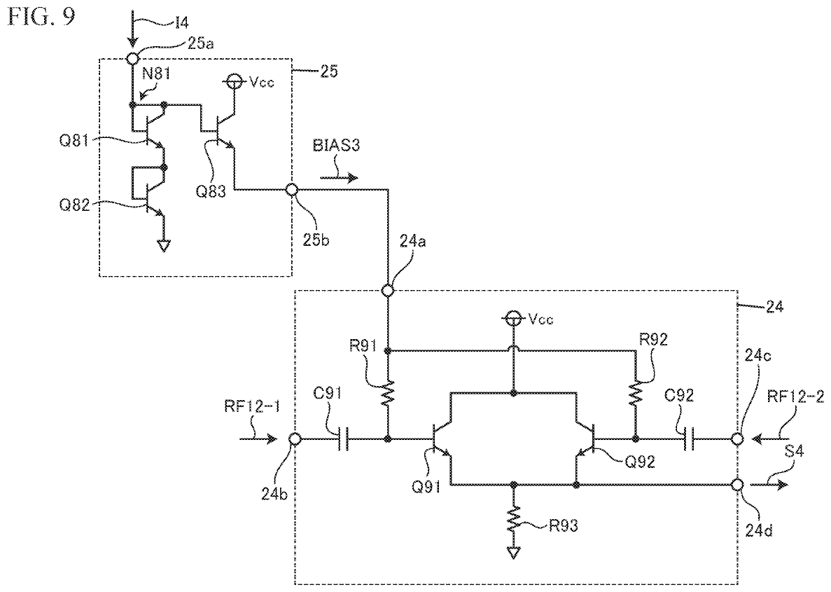

FIG. 9 is a diagram showing a specific example of a circuit configuration of a detector circuit of the Doherty amplifier circuit of the second embodiment.

The detector circuit 24 is biased by a bias circuit 25.

The bias circuit 25 includes transistors Q81 to Q83.

A setting current I4 is input to a terminal 25a of the bias circuit 25.

The collector and the base of the transistor Q81 are electrically connected to the terminal 25a with a node N81 interposed therebetween. That is, the transistor Q81 is diode-connected.

The collector and the base of the transistor Q82 are electrically connected to the emitter of the transistor Q81. That is, the transistor Q82 is diode-connected. The source of the transistor Q82 is electrically connected to the reference potential.

The transistor Q81 and the transistor Q82 generate a voltage depending on the setting current I4. This voltage is the voltage at the node N81.

The collector of the transistor Q83 is electrically connected to the power supply potential Vcc. The base of the transistor Q83 is electrically connected to the node N81. The emitter of the transistor Q83 is electrically connected to a terminal 25b. The transistor Q83 outputs a bias voltage or a bias current BIAS3 from the terminal 25b.

The detector circuit 24 includes transistors Q91 and Q92, capacitors C91 and C92, and resistors R91 to R93.

The bias voltage or the bias current BIAS3 is input to a terminal 24a of the detector circuit 24. A first-phase high frequency signal RF12-1 is input to a terminal 24b of the detector circuit 24. A second-phase high frequency signal RF12-2 is input to a terminal 24c of the detector circuit 24.

When the carrier amplifier 12 (refer to FIG. 8) is a differential amplifier, the carrier amplifier 12 outputs the first-phase high frequency signal RF12-1 and the second-phase high frequency signal RF12-2 to the detector circuit 24. When the carrier amplifier 12 is a single-ended amplifier, a balun may be used. The single-ended high frequency signal RF12 output from the carrier amplifier 12 is input to the balun. The balun converts the single-ended high frequency signal RF12 into the first-phase high frequency signal RF12-1 and the second-phase high frequency signal RF12-2, and outputs the first-phase high frequency signal RF12-1 and the second-phase high frequency signal RF12-2 to the detector circuit 24.

Hereinafter, the first-phase high frequency signal RF12-1 and the second-phase high frequency signal RF12-2 may be collectively referred to as the high frequency signal RF12.

One end of the resistor R91 is electrically connected to the terminal 24a. The other end of the resistor R91 is electrically connected to the base of the transistor Q91. The resistor R91 receives the bias voltage or the bias current BIAS3 and outputs the bias voltage or the bias current to the base of the transistor Q91.

One end of the capacitor C91 is electrically connected to the terminal 24b. The other end of the capacitor C91 is electrically connected to the base of the transistor Q91. The capacitor C91 is a DC cut capacitor that cuts a DC component of the first-phase high frequency signal RF12-1.

One end of a resistor R92 is electrically connected to the terminal 24a. The other end of the resistor R92 is electrically connected to the base of the transistor Q92. The resistor R92 receives the bias voltage or the bias current BIAS3 and outputs the bias voltage or the bias current to the base of the transistor Q92.

One end of a capacitor C92 is electrically connected to the terminal 24c. The other end of the capacitor C92 is electrically connected to the base of the transistor Q92. The capacitor C92 is a DC cut capacitor that cuts a DC component of the second-phase high frequency signal RF12-2.

The collector of the transistor Q91 is electrically connected to the power supply potential Vcc. The emitter of the transistor Q91 is electrically connected to one end of the resistor R93.

The collector of the transistor Q92 is electrically connected to the power supply potential Vcc. The emitter of the transistor Q92 is electrically connected to one end of the resistor R93.

That is, the transistor Q91 and the transistor Q92 configure a differential pair.

One end of the resistor R93 is electrically connected to a terminal 24d. The other end of the resistor R93 is electrically connected to the reference potential.

When the amplitude of the high frequency signal RF12 increases, the current flowing through the resistor R93 increases, and the voltage drop generated across the resistor R93 increases. That is, the voltage of the signal S4 rises. When the amplitude of the high frequency signal RF12 decreases, the current flowing through the resistor R93 decreases, and the voltage drop generated across the resistor R93 decreases. That is, the voltage of the signal S4 falls.

The drive level detection circuit 22 (refer to FIG. 3) sets the sensitivity (gain) or the threshold value by the signal S4 instead of the signal S1. In other words, the drive level detection circuit 22 outputs the signal S2 representing the drive level of the carrier amplifier 13 to the operation circuit 23, based on both the detection result of the input signal to the carrier amplifier 13, which is output from the detector circuit 24, and the high frequency signal RF13, which is output from the carrier amplifier 13.

### Effects

The detector circuit 24 sets the sensitivity or the threshold value of the drive level detection circuit 22 by detecting the high frequency signal RF12, which is the input signal of the carrier amplifier 13. The drive level detection circuit 22 detects the saturation of the carrier amplifier 13 with the set sensitivity or threshold value. Therefore, the Doherty amplifier circuit 1A can rapidly activate the peak amplifier 14 and the peak amplifier 15. Accordingly, the Doherty amplifier circuit 1 can suppress a decrease in quality of the high frequency signal RFout.

The Doherty amplifier circuit 1A can be considered to operate in a feedforward manner depending on the high frequency signal RF12 and to operate in a feedback manner depending on the drive level of the carrier amplifier 13.

The detector circuit 24 sets the sensitivity or the threshold value of the drive level detection circuit 22 by detecting the high frequency signal RF12, which is the input signal of the carrier amplifier 13. Accordingly, the power consumption can be reduced as compared to a case where the sensitivity or the threshold value of the drive level detection circuit 22 is set using the current monitoring circuit 21 (refer to FIG. 1). When the detector circuit 24 is used, it is optional to generate a voltage drop in the path through which the supply current I_{CD} flows as in the case of using the current monitoring circuit 21. Therefore, according to the configuration in which the sensitivity or the threshold value of the drive level detection circuit 22 is set using the detector circuit 24, it is possible to further improve the efficiency of the Doherty amplifier circuit 1A.

### Configuration Example of Present Disclosure

The present disclosure can also have the following configuration.

(1) A Doherty amplifier circuit including:
a carrier amplifier that amplifies a high frequency signal;
a peak amplifier that amplifies the high frequency signal; and
a control circuit that detects a drive level of the carrier amplifier with reference to a detection result of an input signal of the carrier amplifier and controls the peak amplifier based on a detection result.

(2) The Doherty amplifier circuit according to the above (1), in which the control circuit detects the drive level of the carrier amplifier based on a supply current of an amplifying transistor in the carrier amplifier.

(3) The Doherty amplifier circuit according to the above (2), in which the control circuit has a sensitivity or a threshold value for detecting the drive level of the carrier amplifier set by the supply current.

(4) The Doherty amplifier circuit according to the above (1), in which the control circuit detects the input signal of the carrier amplifier, and detects the drive level of the carrier amplifier based on a detection result.

(5) The Doherty amplifier circuit according to the above (4), in which the control circuit has a sensitivity or a threshold value for detecting the drive level of the carrier amplifier set by the detection result of the input signal of the carrier amplifier.

The above-described embodiment is for facilitating the understanding of the present disclosure, and is not intended to limit or interpret the present disclosure. The present disclosure can be modified or improved without necessarily departing from the spirit of the present disclosure, and the present disclosure also includes equivalents thereof.

What is claimed is:

1. A Doherty amplifier circuit comprising:
a carrier amplifier configured to amplify a high frequency signal;
a peak amplifier configured to amplify the high frequency signal; and
a control circuit configured to detect a drive level of the carrier amplifier based on an input of the carrier amplifier, and to control the peak amplifier based on the detected drive level.

2. The Doherty amplifier circuit according to claim 1, wherein the control circuit is configured to detect the drive level of the carrier amplifier based on a supply current of an amplifying transistor in the carrier amplifier.

3. The Doherty amplifier circuit according to claim 2, wherein the control circuit has a sensitivity or a threshold value for detecting the drive level of the carrier amplifier based on the supply current.

4. The Doherty amplifier circuit according to claim 1, wherein the control circuit is configured to detect the input signal of the carrier amplifier, and to detect the drive level of the carrier amplifier based on the detected input signal.

5. The Doherty amplifier circuit according to claim 4, wherein the control circuit has a sensitivity or a threshold value for detecting the drive level of the carrier amplifier based on the detected input signal of the carrier amplifier.
